(19) United States
(12) Patent Application Publication
(10) Pub. No.: US 2004/0005748 A1
(43) Pub. Date: Jan. 8, 2004

(54) Methods of forming a gate insulating layer in an integrated circuit device in which the gate insulating layer is nitrified and then annealed to cure defects caused by the nitridation process

(76) Inventors: Sang-Jin Hyun, Gwacheon-City (KR); Sug-Hun Hong, Suwon-City (KR); Yu-Gyun Shin, Sungnam-City (KR); Jae-Yoon Yoo, Seoul (KR); Hyun-Duk Cho, Hyungsangnam-do (KR)

Correspondence Address: MYERS BIGEL SIBLEY & SAJOVEC, PO BOX 37428, RALEIGH, NC, 27627, US

(21) Appl. No.: 10/400,818

(22) Filed: Mar. 27, 2003

(30) Foreign Application Priority Data
Jul. 5, 2002 (KR) 2002-0038885

(51) Int. Cl. H01L 21/336

(52) U.S. Cl. 438/197

(57) ABSTRACT

A gate insulating layer in an integrated circuit device is formed by forming a gate insulating layer on a substrate. The gate insulating layer is nitrified with plasma and then annealed using oxygen radicals. The oxygen radicals may cure defects in the gate insulating layer caused by the nitridation process. As a result, leakage current may be reduced.

### RELATED APPLICATION

This application claims the benefit of Korean Patent Application No. 2002-38885, filed Jul. 5, 2002, the disclosure of which is hereby incorporated herein by reference.

### FIELD OF THE INVENTION

The present invention relates generally to methods of forming integrated circuit devices and, more particularly, to methods of forming gate insulating layers in integrated circuit devices.

### BACKGROUND OF THE INVENTION

As the integration density of integrated circuit devices increases, the need for gate insulating layers having good electrical characteristics may also increase. A silicon oxide layer used as a gate insulating layer is typically formed by exposing a silicon substrate to an oxidation atmosphere at a high temperature of about 750-1100° C. and at atmospheric pressure. To reduce leakage current flowing through the gate insulating layer and to prevent boron (B) from penetrating from a boron doped dual polygate into the gate insulating layer, a method of plasma nitrifying the gate insulating layer may be used. After the plasma nitridation process, however, the gate insulating layer may or may not be damaged by the plasma depending on the conditions of the plasma nitridation process. In particular, if the gate insulating layer is exposed to plasma for a long period of time or is exposed to high-energy plasma, then the leakage current may increase 1000 times or more and, as a result, the reliability of the gate insulating layer may deteriorate. This may prevent the gate insulating layer from being able to be used in an integrated circuit device.

FIG. 1 shows increases in leakage current due to damage caused by plasma after performing decoupled plasma nitridation (DPN). In FIG. 1, the x-axis and the y-axis represent gate voltage and leakage current density, respectively. As seen in FIG. 1, in each of an NMOS transistor and a PMOS transistor, leakage current density (b) after DPN is increased compared to leakage current density (a) before DPN. In other words, leakage current density increases because the gate insulating layer deteriorates due to silicon dangling bond, oxygen vacancy, or the like occurring after DPN.

### SUMMARY OF THE INVENTION

According to some embodiments of the present invention, a gate insulating layer in an integrated circuit device is formed by forming a gate insulating layer on a substrate. The gate insulating layer is nitrified with plasma and then annealed using oxygen radicals. The oxygen radicals may cure defects in the gate insulating layer caused by the nitridation process. As a result, leakage current may be reduced.

In other embodiments, the oxygen radicals are generated from at least one of N₂O, O₃, and NO₂.

In still other embodiments, the oxygen radicals are generated through thermal disassociation of at least one of N₂O, O₃, and NO₂.

In still other embodiments, the oxygen radicals are generated through in-situ steam generation (ISSG).

In further embodiments, the gate insulating layer is annealed at a pressure of about 3-50 Torr.

In still further embodiments, the gate insulating layer is annealed at a temperature of about 700-1000° C.

In still further embodiments, the gate insulating layer is annealed for about 10-60 seconds.

In other embodiments, the plasma used for nitrifying the gate insulating layer is formed using at least one of nitrogen (N₂) and ammonia (NH₃).

In still other embodiments, the gate insulating layer is nitrified using one of remote plasma, decoupled plasma, slot plane antenna, and electron cyclotron resonance as a plasma source.

### BRIEF DESCRIPTION OF THE DRAWINGS

Other features of the present invention will be more readily understood from the following detailed description of specific embodiments thereof when read in conjunction with the accompanying drawings, in which:

FIG. 1 is a graph that illustrates an increase in leakage current due to plasma damage after decoupled plasma nitridation;

FIGS. 2-5 are cross sectional views that illustrate methods of forming a gate insulating layer and gate insulating layers formed thereby in accordance with some embodiments of the present invention;

FIG. 6 is a graph that illustrates the oxidizing effectiveness of O₂ and N₂O with respect to time and under the same temperature, pressure, and flow rate conditions.

FIG. 7 is a graph that illustrates leakage current that had increased due to the deterioration of a gate insulating layer after DPN, but was then reduced after annealing using N₂O; and

FIG. 8 is a graph that plots leakage current density versus EOT when a gate voltage is −1.5V in a NMOS transistor.

### DETAILED DESCRIPTION OF PREFERRED EMBODIMENTS

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures. In the figures, the dimensions of layers and regions are exaggerated for clarity. It will also be understood that when an element, such as a layer, region, or substrate, is referred to as being “on” another element, it can be directly on the other element or intervening elements may be present. In contrast, when an element, such as a layer, region, or substrate, is referred to as being “directly on” another element, there are no intervening elements present.

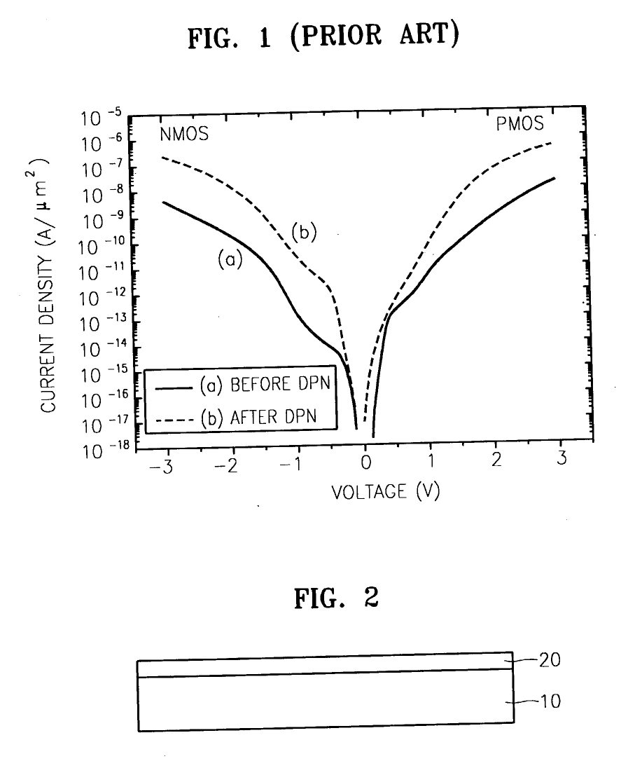

Referring now to FIG. 2, a gate insulating layer 20 is formed on a silicon substrate 10. Silicon oxide may be used for the gate insulating layer 20. For example, in accordance with various embodiments, the silicon substrate 10 can be placed in a rapid thermal oxidation atmosphere, a furnace thermal oxidation atmosphere, or a plasma oxidation atmosphere so that silicon oxide can be formed thereon. In the case of rapid thermal oxidation, a substrate is heated to a temperature of about 800-950° C. at a gas pressure of several Torr for about 10-30 seconds so that oxide can be formed. In this case, heating is performed using infrared rays from a tungsten halogen lamp or an arc lamp. If necessary, instead of silicon oxide, silicon nitride, tantalum oxide, aluminium oxide, or the like may be deposited on the silicon substrate 10 to form the gate insulating layer 20.

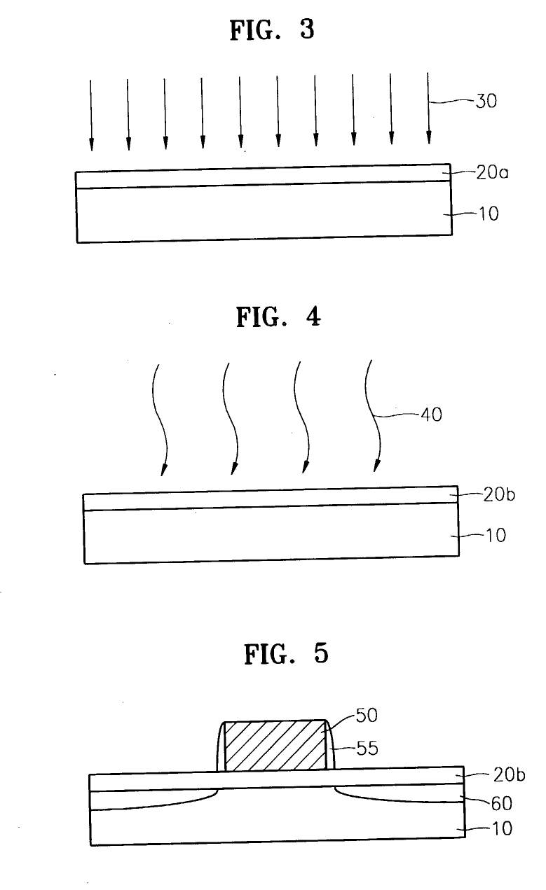

Referring now to FIG. 3, the gate insulating layer 20 undergoes plasma nitridation 30 to reduce leakage current flowing through the gate insulating layer 20 and, subsequently, to prevent boron from penetrating from a dual polygate doped with boron (B) into the gate insulating layer 20. For example, the silicon substrate 10 on which the gate insulating layer 20 is formed is mounted in a vacuum chamber, nitrogen (N₂), ammonia (NH₃), or both N₂ and NH₃ is supplied into the vacuum chamber, and a radio frequency (RF) field is applied to the vacuum chamber to turn N₂ or NH₃ into a plasma state. In this case, helium (He) is used as a carrier gas. For plasma nitridation 30, remote plasma, decoupled plasma, slot plane antenna, or electron cyclotron resonance may be used as a plasma source. In other embodiments, plasma may be obtained from helicon, a parallel plate, transformer coupled plasma called inductively coupled plasma (ICP), or through glow discharge. If decoupled plasma is used, then plasma nitridation 30 is performed for about 10-80, N₂ or NH₃ is supplied into the vacuum chamber, and the pressure is kept at about 5-80 mTorr. The silicon substrate 10 is not heated.

Plasma nitridation 30 converts the gate insulating layer 20 into a gate insulating layer 20a containing nitrogen. Because the gate insulating layer 20a contains a relatively large amount of nitrogen, the insulating constant of the gate insulating layer 20a increases, which results in a reduction in an equivalent oxide thickness (EOT). As discussed above, when the gate insulating layer 20 is exposed to plasma in a plasma nitridation process using a high concentration of nitrogen for a long period of time or is exposed to high-energy plasma, then the gate insulating layer 20 may be damaged by the plasma, which may cause leakage current to increase.

To reduce the flow of leakage current through the gate insulating layer 20a after plasma nitridation 30, the gate insulating layer 20a undergoes annealing 40 using oxygen radicals as shown in FIG. 4. The oxygen radicals may be generated from N₂O, O₃, NO₂, or a combination of N₂O, O₃, and/or NO₂, and/or through in-situ steam generation (ISSG). The oxygen radicals may be generated through heat dissociation. For example, when the silicon substrate 10 on which the gate insulating layer 20a is formed is placed into a furnace, N₂O, O₃, NO₂, or a combination of N₂O, O₃, and/or NO₂ is supplied into the furnace, the pressure in the furnace is maintained at about several, e.g., 3 to 50 Torr, the temperature is set to about 700-1000° C., preferably 950° C., and then annealing 40 is performed for about 10-60 seconds. Through annealing 40, the gate insulating layer 20a becomes a gate insulating layer 20b in which oxygen and nitrogen are relatively well balanced.

Embodiments of the present invention incorporate annealing using N₂O, O₃, and/or NO₂ and/or ISSG capable of creating oxygen radicals so as to cure potential damage to the gate insulating layer 20a caused by plasma nitridation 30. Because damage to the gate insulating layer 20a caused by plasma is primarily on a surface, the oxygen radicals rapidly react with the gate insulating layer 20a so as to remove dangling silicon bonds and oxygen vacancies. The simple decomposition of N₂O into N₂ and O can reduce the oxidation of the silicon substrate 10 and cure damage to the surface of the gate insulating layer 20a. Because annealing 40 using oxygen radicals, i.e., oxidation using oxygen radicals, has a relatively efficient oxidizing power, annealing 40 may cure damage to the gate insulating layer 20a due to plasma. The oxygen radicals do not directly react with the silicon substrate 10 so they do not increase the thickness of the gate insulating layer 20a. Also, annealing 40 using the oxygen radicals has an applicable thermal budget thereto. Moreover, in annealing 40, the concentration of nitrogen after plasma nitridation 30 is maintained. Thus, leakage current flowing through a gate insulating layer can be reduced while maintaining the efficiency of plasma nitridation, thereby forming a gate insulating layer having generally good electrical characteristics.

The gate insulating layer 20b formed through the above-described operations may be used in a variety of embodiments according to the present invention. Referring now to FIG. 5, a conductive layer is formed on the gate insulating layer 20b and patterned to form a gate electrode 50. An insulator, such as silicon nitride or the like, is deposited on the gate electrode 50, and then anisotropically etched to form spacers 55 on sidewalls of the gate electrode 50. Impurities are implanted into the silicon substrate 10 using the gate electrode 50 and the spacers 55 as a mask to form source/drain regions 60 in portions of the silicon substrate 10 under both sidewalls of the gate electrode 50. Through plasma nitridation 30 and annealing 40 using oxygen radicals, the gate insulating layer 20b comprises a generally balanced amount of oxygen and nitrogen atoms. Because the gate insulating layer 20b comprises a substantial number of nitrogen atoms, the equivalent oxide thickness (EOT) is reduced with an increase in the insulating constant of the gate insulating layer 20b. Also, because the oxygen radicals in annealing 40 cure the gate insulating layer 20b damaged by plasma, hot carriers are inhibited from being injected into the drain region 60, which reduces the flow of leakage current through the gate insulating layer 20b. Furthermore, by nitridation 30, even if the gate electrode 50a is embodied as a dual polygate doped with boron, the penetration of boron into the gate insulating layer 20b can be reduced.

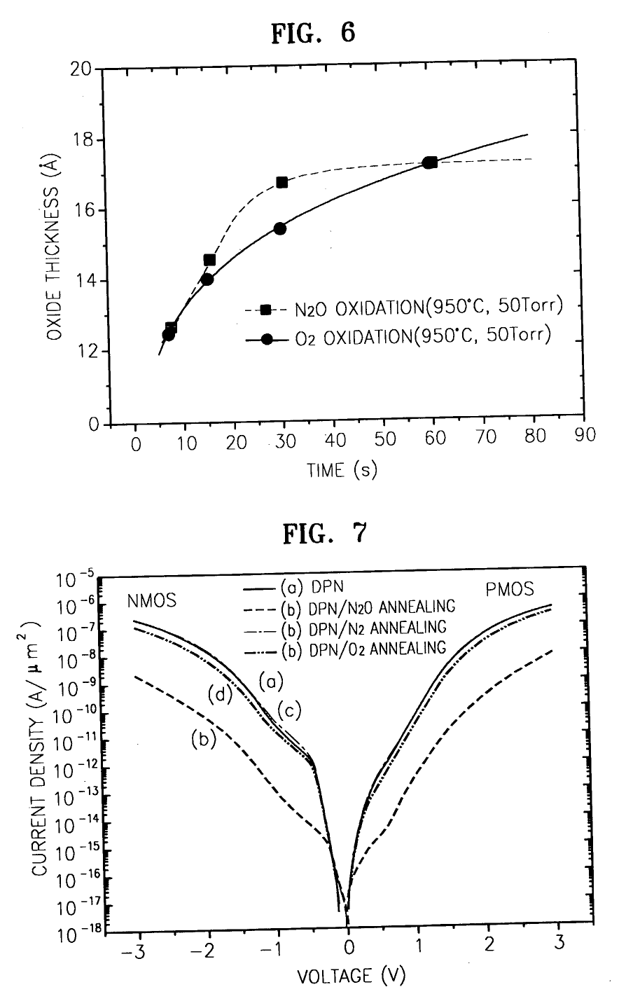

FIG. 6 is a graph that illustrates the oxidizing effectiveness of O₂ and N₂O with respect to time and under the same temperature, pressure, and flow rate conditions. In FIG. 6, black circles and black squares represent the oxidizing effectiveness of O₂ and the oxidizing effectiveness of N₂O, respectively, and the x-axis and the y-axis represent time and oxide thickness, respectively. In the oxidation process, the temperature was 950° C., and the pressure in a furnace was 50 Torr. Referring to FIG. 6, when N₂O was used, the oxide layer grew more rapidly early in the oxidation process. When the oxide reached a predetermined thickness after a predetermined period of time, e.g., a thickness of 17 Å or more, however, the oxide layer grew more slowly. This is because early in the oxidation process, oxygen atoms decomposed from N₂O directly participate in an oxidation reaction; however, after the oxygen atoms form an oxide layer having a predetermined thickness, the oxygen atoms react only when NO or O₂ is diffused to the interface between the silicon substrate 10 and the gate insulating layer 20a. In other words, in a case where oxygen atoms are the main oxidation source, the oxygen atoms mainly react on the surface of the gate insulating layer 20a and not at the interface between the silicon substrate 10 and the gate insulating layer 20a. Thus, when a base oxide layer, i.e., the gate insulating layer 20a, exists, radical oxidation annealing does not greatly affect an increase in the thickness of the oxide layer. Therefore, according to embodiments of the present invention, although a gate insulating layer is annealed using oxygen radicals created from N₂O, the physical thickness of the gate insulating layer varies little. Besides N₂O, annealing using O₃, NO₂, and/or an ISSG also do not generally affect the physical thickness of the gate insulating layer.

FIG. 7 is a graph that illustrates leakage current that had increased due to the deterioration of a gate insulating layer after DPN, but was then reduced after annealing using N₂O. In FIG. 7, the x-axis and the y-axis represent gate voltage and leakage current density, respectively. Also, in FIG. 7, (a) represents leakage current after only DPN is performed, and (b) represents leakage current when annealing is performed using oxygen radicals created from N₂O after DPN. Here, annealing was performed for 15 seconds with a gas pressure maintained at 50 Torr and a temperature set to 950° C. As illustrated in FIG. 7, leakage current shown in (b) was about 100 times less than leakage current shown in (a). In addition, (c) and (d) represent leakage currents after annealing was performed using N₂ and O₂, respectively. As shown in (c) and (d), although annealing was performed, leakage currents did not vary compared to (a). Thus, according to embodiments of the present invention, annealing is preferably performed using gas generating oxygen radicals to reduce leakage current. Because oxidation using oxygen radicals cures defects in the gate insulating layer, particularly, defects on the surface of the gate insulating layer, leakage current flowing through the gate insulating layer is reduced, and the reliability of the gate insulating layer may improve.

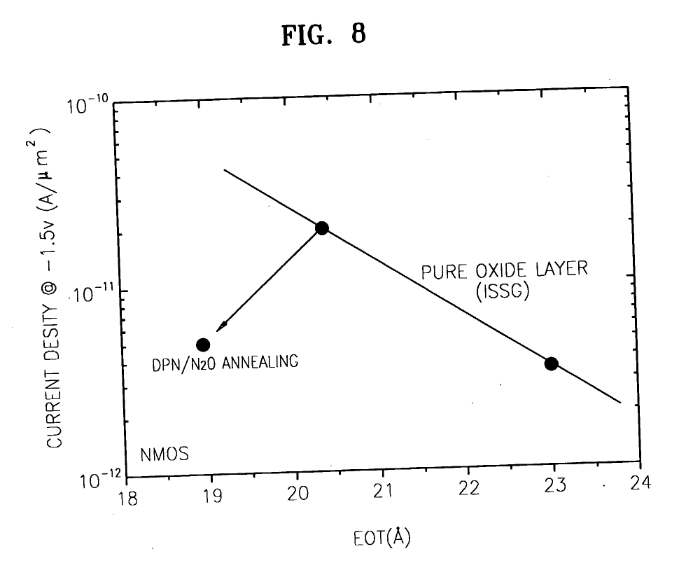

FIG. 8 is a graph that plots leakage current density versus EOT when a gate voltage is −1.5V in a NMOS transistor. As shown in FIG. 8, for a pure oxide layer formed through ISSG is used as a gate insulating layer, when the EOT is about 23 Å, leakage current density is about 1.3×10⁻¹² A/μm², and when the EOT is about 20.3 Å, leakage current density is 1.1×10⁻¹¹ A/μm². In other words, leakage current density increases with a reduction in the EOT, and, thus, in a pure oxide layer, a trade-off exists between a reduction in the EOT and a reduction in the leakage current density.

In a pure oxide layer having a physical thickness of about 20 Å, the EOT is about 20.3 Å, and the leakage current density is 1.1×10⁻¹¹ A/μm². When the pure oxide layer is oxidized using oxygen radicals generated from N₂O, as shown with an arrow, the EOT of the pure oxide layer is reduced to about 19 Å, and the leakage current density is also reduced to 1.5×10⁻¹² A/μm². Thus, because annealing using N₂O reduces leakage current as well as the EOT, the electrical characteristics of a gate insulating layer may be improved by annealing the gate insulating layer using N₂O. Because annealing using O₃, NO₂, and/or ISSG also cures damage due to plasma based on the same principle as annealing using N₂O, the EOT and leakage current can both be reduced by annealing the gate insulating layer using these compounds.

As described above, according to embodiments of the present invention, oxygen radicals generated when decomposing N₂O, O₃, and/or NO₂ rapidly cure silicon dangling bonds and oxygen vacancies on a surface of a gate insulating layer. Because oxidation using oxygen radicals has a relatively efficient oxidizing power, the oxygen radicals rapidly cure damage due to plasma. Advantageously, however, the oxygen radicals do not directly react with a substrate so that they do not greatly increase the physical thickness of a gate insulating layer. Also, because the oxygen radicals remove defects from the gate insulating layer, the EOT as well as the leakage current is reduced.

Accordingly, because the leakage current flowing through the gate insulating layer is reduced while the efficiency of plasma nitridation is maintained, a gate insulating layer having generally good electrical characteristics can be formed. Also, oxidation has an applicable thermial budget thereto. Moreover, the concentration of nitrogen in a gate insulating layer is maintained even after annealing. Based on the same principle as annealing using N₂O, O₃, and/or NO₂, annealing using ISSG to generate oxygen radicals can also prevent leakage current flowing through the gate insulating layer from increasing.

In concluding the detailed description, it should be noted that many variations and modifications can be made to the preferred embodiments without substantially departing from the principles of the present invention. All such variations and modifications are intended to be included herein within the scope of the present invention, as set forth in the following claims.

That which is claimed:

1. A method of forming a gate insulating layer in an integrated circuit device, comprising:
forming a gate insulating layer on a substrate;
nitrifying the gate insulating layer with plasma; and
annealing the nitrified gate insulating layer using oxygen radicals.

2. The method of claim 1, further comprising:
generating the oxygen radicals from at least one of N₂O, O₃, and NO₂.

3. The method of claim 1, further comprising:
generating the oxygen radicals through thermal disassociation of at least one of N₂O, O₃, and NO₂.

4. The method of claim 1, further comprising:
generating the oxygen radicals through in-situ steam generation (ISSG).

5. The method of claim 1, wherein annealing the nitrified gate insulating layer is performed at a pressure of about 3-50 Torr.

6. The method of claim 1, wherein annealing the nitrified gate insulating layer is performed at a temperature of about 700-1000° C.

7. The method of claim 1, wherein annealing the nitrified gate insulating layer is performed for about 10-60 seconds.

8. The method of claim 1, wherein nitrifying the gate insulating layer with plasma comprises:
forming the plasma using at least one of nitrogen (N₂) and ammonia (NH₃).

9. The method of claim 1, wherein nitrifying the gate insulating layer with plasma comprises:
using one of remote plasma, decoupled plasma, slot plane antenna, and electron cyclotron resonance as a plasma source.

10. A method of forming a gate insulating layer in an integrated circuit device, comprising:
forming a gate insulating layer on a substrate;
nitrifying the gate insulating layer with plasma; and
annealing the nitrified gate insulating layer using oxygen radicals generated from at least one of N₂O, O₃, and NO₂ at a pressure of about 3-50 Torr, at a temperature of about 700-1000° C., and for a period of about 10-60 seconds.

11. The method of claim 10, wherein nitrifying the gate insulating layer with plasma comprises:
forming the plasma using at least one of nitrogen (N₂) and ammonia (NH₃).

12. The method of claim 10, wherein nitrifying the gate insulating layer with plasma comprises:
using one of remote plasma, decoupled plasma, slot plane antenna, and electron cyclotron resonance as a plasma source.
